(19) United States
(12) Patent Application Publication
(10) Pub. No.: US 2004/0206804 A1
(43) Pub. Date: Oct. 21, 2004

(54) Traps for particle entrapment in deposition chambers

(76) Inventors: Jaeyeon Kim, Liberty Lake, WA (US); John D. Mize, Spokane Valley, WA (US); Terry J. Phelan, Spokane, WA (US)

Correspondence Address: WELLS ST. JOHN P.S., 601 W. FIRST AVENUE, SUITE 1300, SPOKANE, WA, 99201, US

(21) Appl. No.: 10/837,555

(22) Filed: Apr. 30, 2004

Related U.S. Application Data
(63) Continuation-in-part of application No. 10/614,806, filed on Jul. 9, 2003.
(60) Provisional application No. 60/477,810, filed on Jun. 11, 2003.
(60) Provisional application No. 60/498,036, filed on Aug. 26, 2003.
(60) Provisional application No. 60/396,543, filed on Jul. 16, 2002.

(51) Int. Cl. C23C 14/32; B23K 28/00

(52) U.S. Cl. 228/199; 204/298.12; 228/193

(57) ABSTRACT

The invention includes deposition apparatuses having reaction chambers and particle-trapping features formed along one or more surfaces within the chambers. In particular aspects, the particle-trapping features can comprise a pattern of bent projections forming receptacles, and can comprise microstructures on the bent projections. The invention also includes methods of forming particle-trapping features by initially forming a pattern of projections, bending the projections, and then exposing the projections to particles to form microstructures on the bent projections.

### RELATED PATENT DATA

This patent has priority to U.S. Provisional Application Serial No. 60/477,810, filed Jun. 11, 2003, and to U.S. Provisional Application Serial No. 60/498,036, filed Aug. 26, 2003; additionally, this patent is a continuation-in-part of U.S. patent application Ser. No. 10/614,806, filed Jul. 9, 2003, which claims priority to U.S. Provisional Application Serial No. 60/396,543, which was filed Jul. 16, 2002.

### TECHNICAL FIELD

The invention pertains to methods of forming traps for particle entrapment in deposition chambers and in particular aspects pertains to methods of forming roughened surfaces on chamber components exposed to deposition conditions. The roughened surfaces can be formed on, for example, one or more of a target, flange, shield, cover ring, coil, cup, pin and/or clamp.

### BACKGROUND OF THE INVENTION

Deposition methods are utilized for forming films of material across substrate surfaces. Deposition methods can be utilized in, for example, semiconductor fabrication processes to form layers ultimately utilized in fabrication of integrated circuitry structures and devices. Exemplary deposition methods are chemical vapor deposition (CVD), atomic layer deposition (ALD), metalorganic chemical vapor deposition (MOCVD) and physical vapor deposition (PVD). PVD methodologies include sputtering processes.

Problems can occur in deposition processes if particles are formed, in that the particles can fall into a deposited film and disrupt desired properties of the film. Accordingly, it is desired to develop traps which can alleviate problems associated with particles falling into a deposited material during deposition processes.

### SUMMARY OF THE INVENTION

In particular aspects of the invention, it is found that a bent scroll pattern formed on one or more surfaces within a deposition chamber can function as a particle trap and provide significant improvement in reducing problems associated with particle formation in deposition chambers. The particle, traps can be utilized in numerous deposition applications, including, for example, PVD, CVD, MOCVD and ALD. In PVD applications, the particle traps can be formed on any chamber component or combination of components, including, for example, target flanges, target sidewalls, shields, cover rings, coils, cups, pins and/or clamps.

Particle traps formed in accordance with the present invention can, in particular aspects, be formed through machine scrolling and/or knurling which imparts a macro-scale roughness on a treated surface. The macro-scale roughness can subsequently be treated with bead blasting or other suitable processing to create a micro-scale roughness which can further enhance particle trapping.

In some aspects, macro-scale bent scrolling can geometrically protect potential particle fall off. Additionally, micro-scale surface roughening imparted onto the macro-scale bent scroll can alleviate cyclic thermal stress during a deposition process. In some aspects, the machined scroll (and/or surface texturing produced by other methodologies, such as, for example, knurling and bead blasting) can create re-deposited long films which are vulnerable to thermal stresses associated with different thermal expansion coefficients of the re-deposited film and base material of a treated surface. However, reduction of thermal stress can occur from discontinuously redeposited films utilizing a rough texture associated with, for example, a bent scroll pattern.

In one aspect of the invention, one or more components of a deposition chamber are treated to form roughened surfaces on the one or more components. The roughened surfaces can be formed by utilizing one or more suitable tools to form a repeating pattern of projections along the surfaces of the components. The projections can be in the form of, for example, a scroll pattern. In subsequent processing, the projections can be folded by exposing the projections to, for example, a roller. The projections can alternatively, or additionally, be subjected to bead blasting, or other suitable processing, to form a micro-scale roughness on the projections.

Some attempts have been made previously to utilize knurling or bead blasting to treat deposition chamber components, but over time materials can deposit on the components and peel or flake from the treated areas. Methodology of the present invention can alleviate, and even entirely avoid, peeling, flaking and other undesired problems associated with knurling and bead blasting treatments.

Exemplary aspects of the invention utilize a bent scroll having macro-scale and micro-scale particle trapping features associated therewith. The micro-scale and macro-scale design of an exemplary bent scroll of the present invention can trap particles effectively while reducing or even minimizing peeling issues, and while also avoiding potential arcing associated with sharp points. An exemplary surface treatment of the present invention can be accomplished with the one or more of the following three processes:

1. creation a macro-scale trapping region, (e.g., formation of a bent scroll);

2. creation of a micro-scale trapping region, (e.g., bead-blast formation of a roughened surface); and

3. modification of a surface chemistry within a trapping area to enhance the adhesion of materials within the trapping region.

In one aspect, the invention includes treating surface projections of component suitable for utilization in deposition chamber. The treating comprises: (1) exposing the projections to a chemical etchant or pitting agent to impart microstructural roughness to the surface projections, and/or (2) exposing the projections to a volatile bead blast media to impart microstructural roughness to the surface projections, and/or (3) exposing the projections to a bead blast media which is soluble in a solvent to impart microstructural roughness to the surface projections followed by cleaning of the bead blast media from the microstructural roughness with the solvent.

### BRIEF DESCRIPTION OF THE DRAWINGS

Preferred embodiments of the invention are described below with reference to the following accompanying drawings.

FIG. 1 is a diagrammatic, cross-sectional view of a physical vapor deposition apparatus shown during a physical vapor deposition (e.g., sputtering) process.

FIG. 2 is a cross-sectional view of the FIG. 1 apparatus shown along the line 2-2 of FIG. 1.

FIG. 3 is a diagrammatic, top view of a coil at a preliminary processing stage of an exemplary method of the present invention.

FIG. 4 is a view of an expanded region of the FIG. 3 coil shown at the processing stage of FIG. 3.

FIG. 5 is a view of the FIG. 4 expanded region shown at a processing stage subsequent to that of FIG. 4.

FIG. 6 is a view of the FIG. 4 expanded region shown at a processing stage subsequent to that of FIG. 5.

FIG. 7 is an expanded view of a portion of the FIG. 6 structure.

FIG. 8 is a view of the FIG. 4 expanded region shown a processing stage subsequent to that if FIG. 6.

FIG. 9 is an expanded view of the structure shown in FIG. 8.

FIGS. 10-17 are copies of photomicrograph images showing exemplary roughened surfaces which can be utilized in exemplary aspects of the present invention.

FIG. 18 is a diagrammatic, cross-sectional view of an exemplary CVD and/or ALD deposition apparatus which can be treated in accordance with an aspect of the present invention.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

The invention encompasses new textures which can be formed on one or more surfaces of a deposition process component. The component can be suitable for utilization in, for example, one or more of a PVD, CVD, MOCVD or ALD reaction chamber. The textures can be utilized for trapping materials which deposit on the component during a deposition process. In a particular aspect, curved projections (such as, for example, a bent scroll pattern) are formed on one or more surfaces of the component to form particle trapping areas. If the treated component is a sputtering target, the treated surfaces can include any non-sputtered surfaces, such as, for example, sidewall surfaces, flange surfaces and/or non-sputtered surfaces along a sputtering face.

The projections formed on the component can be exposed to particles to roughen surfaces of the projections to improve trapping properties of the projections. The projections can be considered to form a macroscale roughness of a trapping area, and the roughened surfaces of the projections can be considered to form a microscale roughness of the trapping area. Thus, the invention can include patterns which have both macroscale and microscale roughness, and which are utilized in trapping areas.

The utilization of both macroscale and microscale patterns can be advantageous. The combined patterns can significantly reduce material fall-off from a treated surface of a component during a deposition process. Also, the formation of the microscale roughened surface on the macroscale pattern can effectively reduce problems that may otherwise be associated with cyclic thermal stresses occurring during cyclic deposition processes. Specifically, a macroscale pattern alone (such as, for example, a long machined scroll) can trap redeposited materials to form a long film within a trapping region. Cyclic thermal stresses (such as stresses associated with, for example, a different thermal expansion coefficient of the redeposited film versus the base material of the treated component), can lead to peeling of the film or clusters of redeposited film from the treated component. As the film or cluster peels from the component, it can fall onto a substrate proximate the component to undesirably form particles within a layer deposited on the substrate during a deposition process, which can decrease throughput or yield of the deposition process. If the process is a PVD process, the peeling film or cluster can fall directly onto an electrostatic chuck provided to support the substrate during the PVD process, which can create system failure.

In particular aspects the invention encompasses bead-blasting and/or chemical etching and/or steel brushing and/or other treatment of a macroscale pattern to impart microstructural roughness on the pattern which can ultimately be utilized to assist in retaining redeposited materials within the pattern, and can thus alleviate, or even prevent, peeling of redeposited film materials from the trapping area. In other words, the macroscale and microscale structures can reduce sizes of redeposited clusters, and in particular aspects, can eliminate redeposited clusters from being incorporated into deposited films.

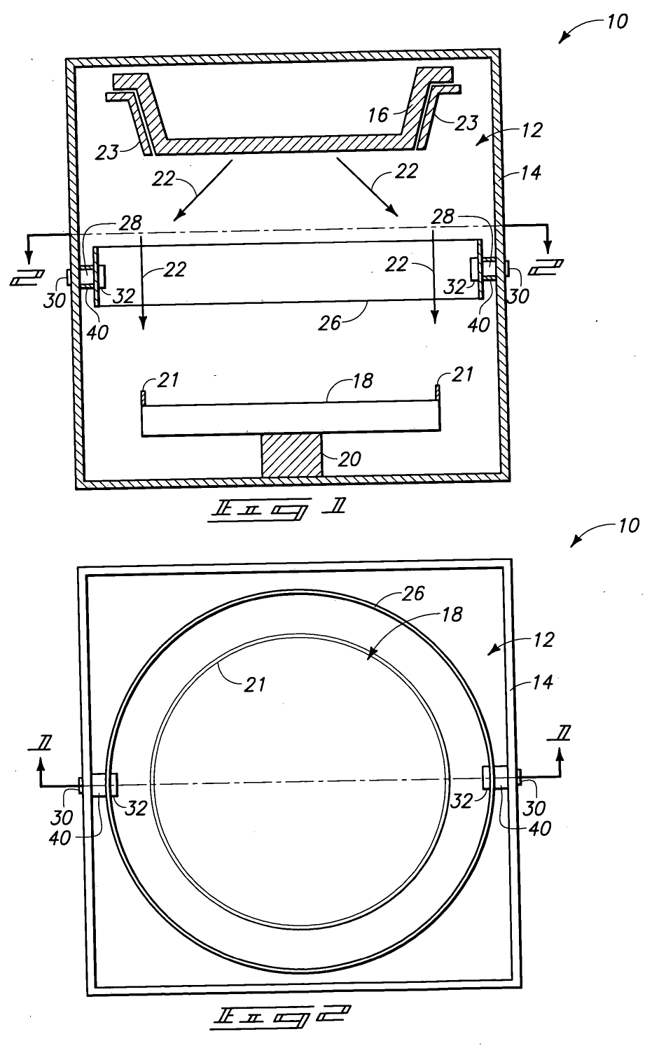

A first exemplary aspect of the invention is described herein with reference to a PVD operation. An exemplary PVD (e.g., sputtering) operation is described with reference to FIGS. 1 and 2. Referring to FIG. 1, a sputtering apparatus 10 comprises a chamber 12 having sidewalls 14. A target 16 is provided in an upper region of the chamber, and a substrate 18 is provided in a lower region of the chamber. Substrate 18 is retained on a holder 20 with a cover ring 21, and target 16 would be retained with suitable supporting members (not shown). A shield 23 is shown shielding edges of the target 16. There can also additional shielding (not shown) along the internal sidewalls and/or internal top of the chamber, as is known to persons of ordinary skill in the art.

Substrate 18 can comprise, for example, a semiconductor wafer, such as, for example, a single crystal silicon wafer. Target 16 can comprise, for example, one or more of nickel, tantalum, titanium, copper, aluminum, silver, gold, niobium, platinum, palladium and ruthenium, including one or more alloys of the various metals; and in particular applications the target can comprise one or more of various mixtures, compounds or alloys including, for example, Ti/N, Ti/Nb, and Ti/Al.

In operation, material is sputtered from a surface of target 16 and directed toward substrate 18. The sputtered material is represented by arrows 22.

Generally, the sputtered material will leave the target surface in a number of different directions. This can be problematic, and it is preferred that the sputtered material be directed relatively orthogonally to an upper surface of substrate 18. Accordingly, a focusing coil 26 is provided within chamber 12. The focusing coil can improve the orientation of sputtered materials 22, and is shown directing the sputtering materials relatively orthogonally to the upper surface of substrate 18. It is noted the coil is optional in some reactor designs.

Some material can be removed from coil 26 during a sputtering operation, and such material can deposit over substrate 18. Accordingly, it can be preferred that coil 26 comprise the same material as target 16, or at least comprise a material which will not adversely affect a sputtering operation.

Coil 26 is retained within chamber 12 by pins 28 which are shown extending through sidewalls of the coil and also through sidewalls 14 of chamber 12. Pins 28 are retained within retaining screws 32 in the shown configuration. The schematic illustration of FIG. 1 shows heads 30 of the pins along the exterior surface of chamber sidewalls 14.

Spacers 40 extend around pins 28, and are utilized to space coil 26 from sidewalls 14. Spacers 40 typically have a cup-like shape, and accordingly are typically referred to as cups.

Numerous support structures are known which are suitable to support a coil (such as coil 26), and the shown utilization of pins, retaining screws and cups is but one example of the numerous support structures. Among the other support structures are, for example, constructions in which the coil is a single piece having a smooth interior dimension, and the pins, cups and other retaining features are incorporated into a boss attached to the coil. The boss can be fabricated to be one-piece with the coil, or can be fabricated as a separate piece from the coil and then subsequently attached to the coil by a suitable means, such as, for example, welding.

FIG. 2 shows a cross-sectional view along the line 2-2 of FIG. 1, and shows that coil 26 typically has a circular shape.

As discussed previously, a problem which can occur during sputter operations is that particles form within a reaction chamber. The particles can form from a number of different sources, including, for example, voids or other minor defects present within target 16. If the particles deposit across the upper surface of substrate 18, they can adversely affect a sputter-deposited layer. Accordingly, it is desired to develop methods for avoiding having particles fall onto the upper surface of substrate 18.

In accordance with the present invention, particle traps can be formed on one or more of the exposed surfaces within chamber 12. The surfaces can, in particular aspects, be associated with one or more of the components in the chamber, including, for example, the target, shields, pins, coil, cover ring, etc.

The roughened surfaces can be formed with appropriate machining. Exemplary processing is described below with reference to machining utilized to form particle traps associated with coil 26, but it is to be understood that similar processing can be applied to surfaces of other components.

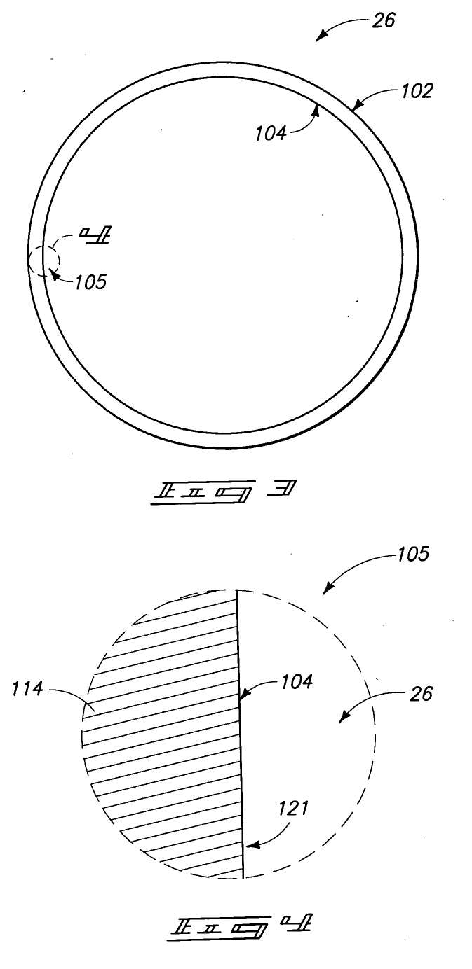

FIG. 3 shows coil 26 at a preliminary processing stage. Coil 26 is an annular ring comprising a radially outer periphery 102 and a radially inner periphery 104. It can be preferred that particle traps be formed along inner periphery 104 relative to outer periphery 102 as particles can be more likely to pass along inner periphery 104 than outer periphery 102. In the processing described below, particle traps are formed only along inner periphery 104 rather than along both of peripheries 102 and 104, but it is to be understood that the invention includes other aspects, (not shown) in which particle traps are formed along periphery 102 additionally to, or alternatively to, formation of the particle traps along periphery 104. If particle traps are formed along both periphery 102 and 104, the traps along periphery 104 can be configured the same as those along periphery 102 or different.

FIG. 4 shows an expanded region 105 of inner periphery 104 at a preliminary processing stage. As shown, the periphery has a relatively planar surface 121 along a structural wall 114. The coil at the processing stage of FIG. 4 can be a conventional commercially available coil.

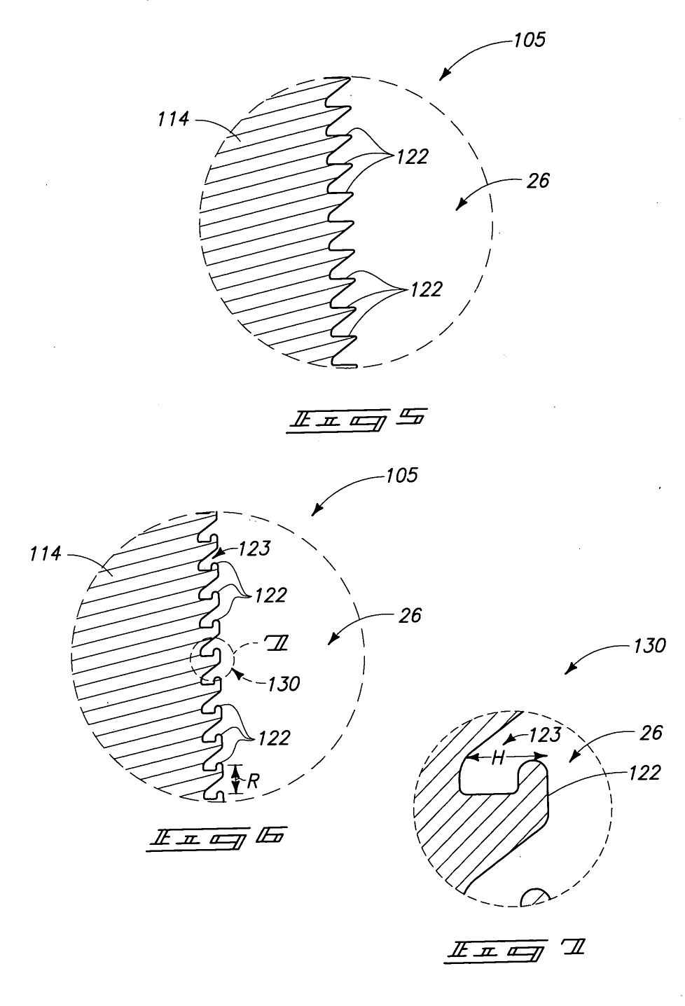

FIG. 5 illustrates expanded region 105 after periphery 104 has been treated to form a pattern of projections 122 extending across a surface of sidewall 114. Projections 122 can be formed utilizing a saw, knurling device, computer numerically controlled (CNC) device, manual lathe or other suitable machining tool, and can correspond to a scroll pattern. Specifically, a saw can be utilized to cut into sidewall 114 and leave the shown pattern and/or a knurling device can be utilized to press into sidewall 114 and leave the pattern. The pattern is a repeating pattern, as opposed to a random pattern that would be formed by, for example, bead blasting. The pattern of projections 122 can be referred to as a macro-pattern to distinguish the pattern from a micro-pattern that can be subsequently formed (discussed below). The projections 122 can be formed with a tool having from about 28 teeth per inch (TPI) to about 80 TPI, with about 40 TPI being typical. The teeth of the tool can be in a one-to-one correspondence with the projections 122. The range of 28 TPI to 80 TPI includes exemplary applications, but the invention is not limited to the range of 28 TPI to 80 TPI. It is to be understood that suitable tools for applications of the present invention can also have less than 28 TPI or more than 80 TPI.

FIG. 6 shows expanded region 105 after the projections 122 have been subjected to a mechanical force which bends the projections over. The mechanical force can be provided by any suitable tool, including, for example, a ball or roller. The bent projections define cavities 123 between the projections, and such cavities can function as particle traps. Preferably the cavities open upwardly in the orientation in which coil 26 is ultimately retained in a sputtering chamber (such as, for example, the chamber 12 of FIG. 1).

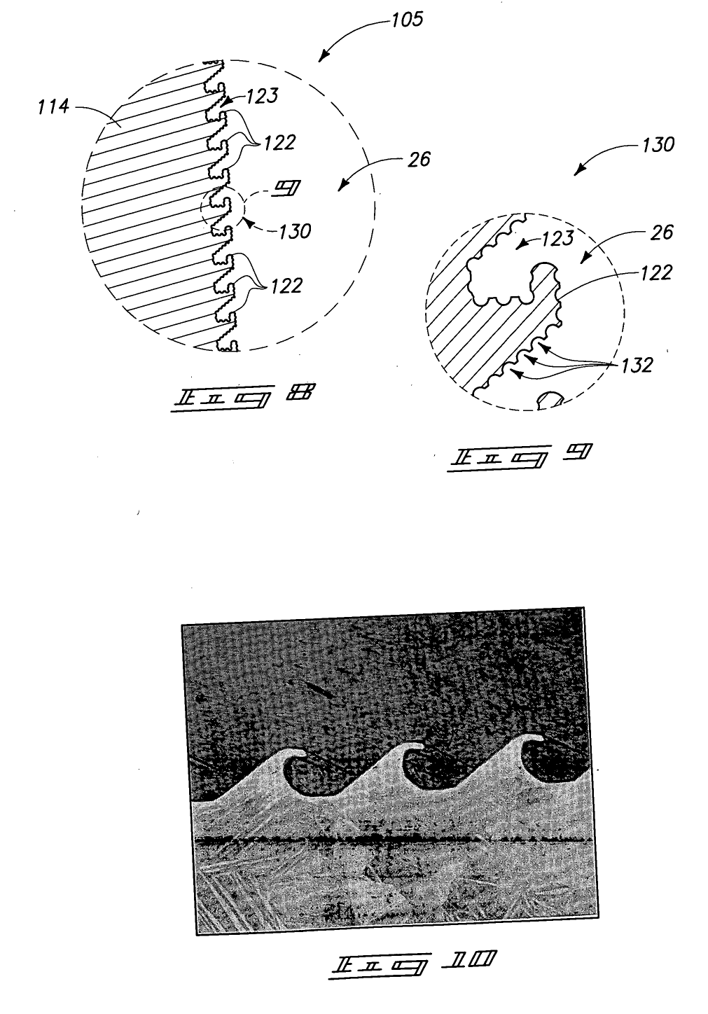

FIG. 7 illustrates an expanded region 130 of the FIG. 6 structure, and specifically illustrates a single projection 122.

The bent projections 122 of FIGS. 6 and 7 can have a height “H” above surface 114 of, for example, from about 0.0001 inch to about 0.1 inch (typically about 0.01 inch), and a repeat distance “R” of from about 0.001 inch to about 1 inch (typically about 0.027 inch).

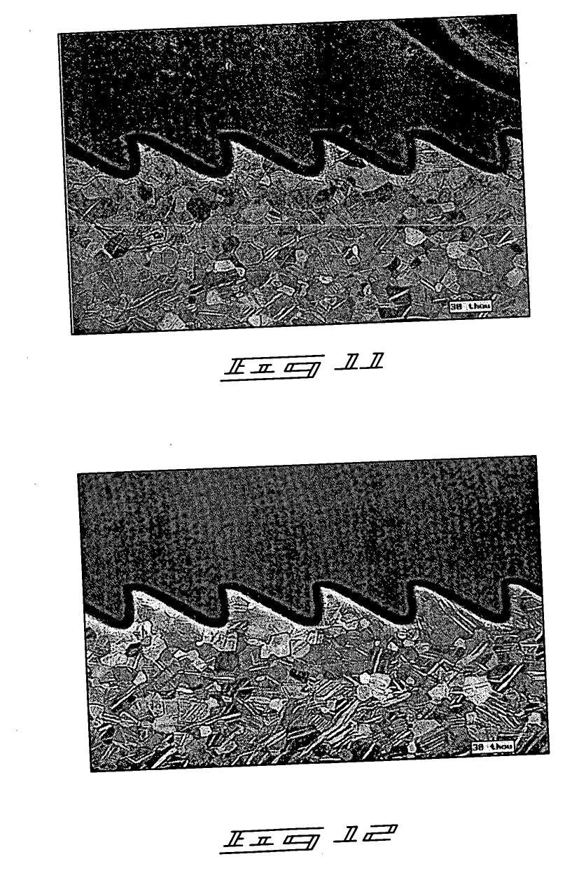

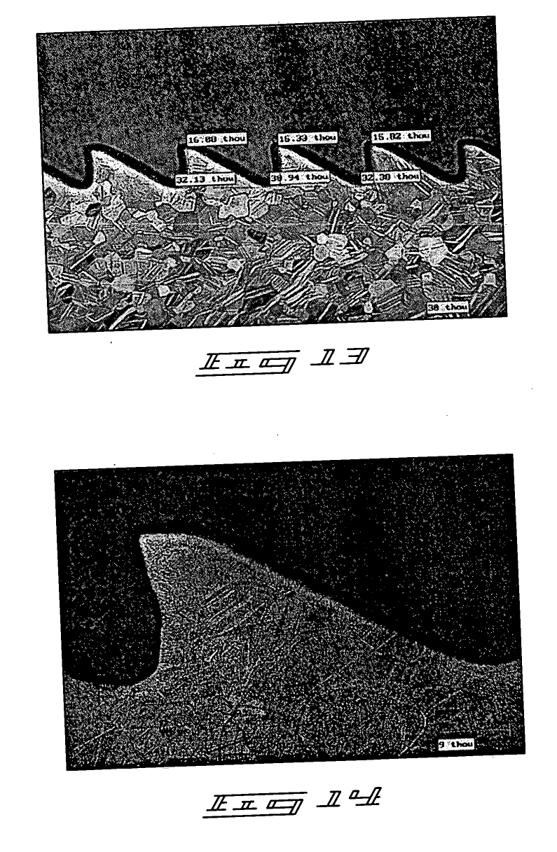

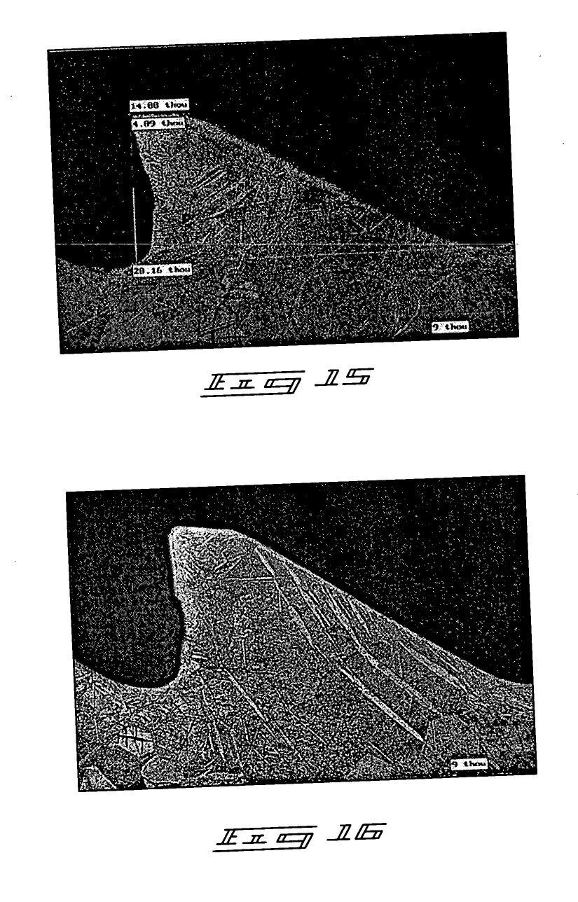

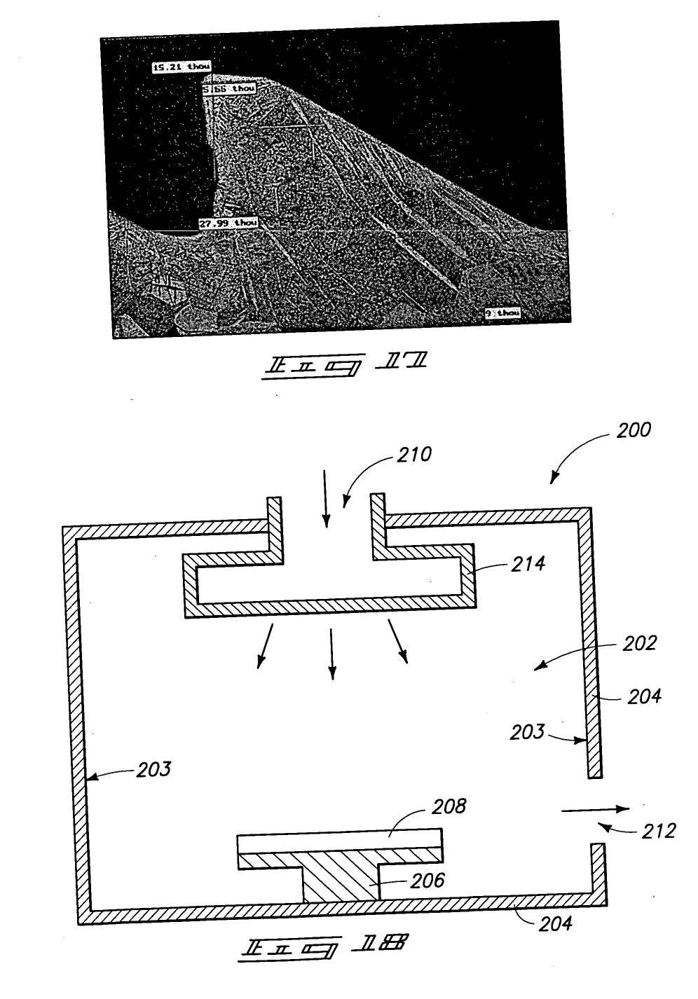

FIGS. 10-17 are photomicrographic images of actual roughened surfaces at the processing stage of FIGS. 6 and 7 in accordance with exemplary aspects of the present invention.

The structure formed to the processing stage of FIGS. 6 and 7 can have suitable particle traps, and can be utilized as is in a sputtering chamber. Alternatively, the structure can be subjected to further processing to form microstructures on the projections 122, which can enhance the particle-trapping capabilities of the projections. The processing utilized to form the microstuctures can comprise, for example, bead blasting and/or chemical treatment.

Although the formation of microstructures is described as following the formation of the macrostructures (i.e., the bent scroll pattern of FIGS. 6 and 7), it is to be understood that the invention includes other aspects in which the formation of the microstructures does not follow the formation of the macrostructures. For instance, if bead blasting is utilized to form the microstructures, the bead blasting can be utilized alone to form a trapping region, and accordingly can be conducted without formation of the bent projections 122 of FIGS. 6 and 7. In yet other aspects, the bead blasting can be conducted after forming a projection, and prior to bending the projection (i.e., at a processing stage between the shown processing stages of FIGS. 5 and 6).

FIGS. 8 and 9 show projections 122 after they have been subjected to bead blasting or other suitable exposure to particles to form microstructures 132 (labeled in FIG. 9) extending within the projections as cavities or divots.

The treatment of projections 122 can utilize, for example, one or both of a chemical etchant and mechanical roughening. Exemplary mechanical roughening procedures include exposure to a pressurized stream of particles (e.g., bead-blasting), or exposure to rigid bristles (such as wire bristles). Exemplary chemical etchants include solutions which chemically pit the material of projections 122, and can include strongly basic solutions, weakly basic solutions, strongly acidic solutions, weakly acidic solutions, and neutral solutions.

If bead blasting is utilized to form microstructures 132, the particles used to form the microstructures can comprise, for example, one or more of silicon carbide, aluminum oxide, solid H₂O (ice), solid carbon dioxide, and salt (such as, for example, a salt of bicarbonate, such as sodium bicarbonate). Additionally or alternatively, the particles can comprise on or more materials at least as hard as the material in which the microstructures are to be formed.

If the particles utilized for the bead-blasting comprise a non-volatile material, a cleaning step can be introduced after formation of divots 132 to remove the particles. For instance, if the particles comprise silicon carbide or aluminum oxide, a cleaning step can be utilized wherein projections 122 are exposed to a bath or stream of cleaning material and/or are brushed with an appropriate brushing tool (such as a wire brush). A suitable stream can be a stream comprising solid H₂O or solid carbon dioxide particles. If the particles initially utilized to form divots 132 consist essentially of, or consist of, volatile particles (such as solid ice or solid CO₂), then the cleaning step described above can be omitted.

In some aspects, the particles are soluble in a fluid and can be suspended in the fluid at sufficient concentration to saturate the fluid with the material of the particles and leave solid particles within the fluid. For instance, the particles can comprise bicarbonate in an aqueous fluid saturated with bicarbonate. The particles and fluid can form desired microstructural roughness through mechanical abrasion and/or through a combination of mechanical abrasion and chemical etching (i.e.,.chemical pitting). The particles can then be cleaned from the treated component by washing the component in a volume of the fluid which is not saturated with the material of the particles to dissolve the particles from the component. In some aspects, the fluid can be an aqueous fluid and can be considered to be utilized in pressurized aqueous mechanical abrasion. The pH of the aqueous treating fluid can be strongly acid, strongly basic, or in between. The washing fluid can be aqueous, and the pH of the aqueous washing fluid can be the same as the treating fluid, or different.

In a particular aspect, the bead-blasting media can be 24 grit Al₂O₃ media, and the bead-blasting can be conducted to, for example, from about 1 to about 4000 micro-inch RA, preferably from about 50 to about 2000 micro-inch RA, and typically from about 100 to about 350 micro-inch RA.

The bead-blasting of the present invention can be conducted at much lower pressures than the pressures typical of prior art processes, which can reduce a likelihood that bead-blasted particles will become embedded in structures treated with the present invention. Specifically, prior art bead-blasting is typically conducted at pressures of at least about 80 pounds per square inch (psi) (i.e., is conducted by pushing particulates at a structure with impact pressures imparted by the particulates on the structure averaging at least about 80 psi). In contrast, bead-blasting of the present invention can be conducted at pressures of less than or equal to 20 psi. To further reduce a likelihood of bead-blasted particles remaining imbedded or otherwise associated with a surface treated in accordance with the present invention, the surface can be cleaned after the bead-blasting by mechanically brushing the surface (utilizing, for example, a wire brush), and/or by spraying the surface with a-volatile cleaning agent (e.g., by blasting the surface with CO₂), and/or by spraying the surface with a non-volatile cleaning agent. As indicated by some of the exemplary aspects described above, in particular aspects the present invention can utilize particulates (e.g., beads) that are soluble in a solvent, and the cleaning can comprise utilization of the solvent to remove the particulates.

As discussed previously, the bead blasting can be conducted in the absence of prior processing to form projections 122. In such aspects, the bead-blasting media can be, for example, 24 grit Al₂O₃ media, and the bead blasting can be conducted to, for example, from about 150 to about 350 micro-inch RA.

The sidewall 114 shown at the processing stage of FIG. 8 can be considered to have a surface having both macro-scale and micro-scale structures formed therein. Specifically, projections 122 can have a length of 0.01 inches, and can be considered to be a macro-scale feature formed on a substrate. The divots formed within the projections can be considered to be micro-scale structures formed along the surface of sidewall 114. The combination of the micro-scale and macro-scale structures can alleviate, and even prevent, the problems described previously in this disclosure regarding undesired incorporation of particles into deposited films.

The processing of coil 26 to form the particle traps described herein can occur at any suitable processing stage during or after fabrication of a conventional coil construction. Similarly, processing of the present invention can be applied to other components of a sputtering apparatus during or after fabrication of the conventional forms of the components. In particular aspects, processing of the present invention will be provided as additional steps after a conventional component is formed so that processing of the present invention can be applied to off-the-shelf components.

The roughening applications described with reference to FIGS. 3-7, with or without the additional applications described in FIGS. 8 and 9, can be applied to any component within a reaction chamber which may be exposed to particles, and which can accordingly be utilized as a particle trap. In the exemplary PVD chamber described with reference to FIGS. 1 and 2, the treated surfaces can include, for example, sidewall surfaces and/or flange surfaces of target 16, surfaces of shield 23, surfaces of pins 40, surfaces of coil 26, interior surfaces of sidewalls 14, and/or surfaces of cover ring 21, among others. The methodology of the present invention can be, for example, applied to process kits (shields, cover rings, coils, etc.). Preferably, the treated surfaces will be configured so that particle trapping cavities associated with the surfaces are upwardly oriented in the orientation in which the surfaces are utilized within the reaction chamber.

As discussed previously, the processing of the present invention can be utilized for treating components of other apparatuses besides PVD apparatus. FIG. 18 illustrates an apparatus 200 that can have one or more portions treated with methodology of the present invention. Apparatus 200 can be a CVD and/or ALD apparatus. The apparatus comprises a reaction chamber 202 and a sidewall 204 extending around the chamber. Sidewall 204 has an inner surface 203 along an interior region of the chamber.

Apparatus 200 further comprises a substrate holder 206 within the chamber. The substrate holder is shown supporting a substrate 208.

An inlet 210 and outlet 212 extend through the sidewall 204 of the chamber. In operation, reactants are flowed into the chamber through the inlet, and materials are exhausted from the chamber through the outlet. Valves (not shown) can be provided across the inlet and outlet to control flow into and out of the chamber.

A dispersion structure 214 is shown beneath the inlet 210. Gas flowed through the inlet can be dispersed by structure 214 so that the gas flows uniformly across a surface of substrate 208. Dispersion structure 214 can comprise a so-called showerhead. The dispersion structure can be omitted in some aspects of the invention.

The macroscale and/or microscale roughening of FIGS. 5-9 can be applied to one or more surfaces within chamber 202. For instance surfaces of dispersion apparatus 214 or substrate holder 206 can be treated, and/or a portion or an entirety of surface 203 can be treated.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

The invention claimed is:

1. A method of treating a component of a deposition apparatus, comprising:
forming a pattern of projections along a surface of the component;
bending the projections; and
exposing the projections to one or both of mechanical roughening and chemical etching to form microstructures on the projections.

2. The method of claim 1 wherein the projections are exposed to the mechanical roughening, and wherein the mechanical roughening comprises exposure of the projections to a rigid bristles.

3. The method of claim 1 wherein the projections are exposed to the mechanical roughening, and wherein the mechanical roughening comprises exposure of the projections to a pressurized stream of particles.

4. The method of claim 3 wherein the particles comprise one or both of solid H₂O and solid CO₂.

5. The method of claim 3 wherein the particles comprise a salt.

6. The method of claim 5 wherein the salt is soluble in water.

7. The method of claim 6 wherein the salt is a salt of bicarbonate.

8. The method of claim 3 wherein the particles comprise one or both of silicon carbide and aluminum oxide; and wherein the exposure of the region to the pressurized stream comprises utilization of a pressure of less than 20 psi within the stream during the-exposure.

9. The method of claim 3 wherein the particles comprise one or both of silicon carbide and aluminum oxide; and further comprising brushing the region after the exposure to the particles.

10. The method of claim 3 wherein the particles comprise one or both of silicon carbide and aluminum oxide; and further comprising exposing the region to a stream of cleaning agent after the exposure to the particles.

11. The method of claim 10 wherein the cleaning agent comprises one or both of solid H₂O and solid CO₂.

12. The method of claim 1 wherein the projections are exposed to the chemical etching, and wherein the chemical etching comprises exposure of the projections to a basic solution.

13. The method of claim 1 wherein the projections are exposed to the chemical etching, and wherein the chemical etching comprises exposure of the projections to an acidic solution.

14. The method of claim 1 wherein the projections are exposed to both the chemical etching and the mechanical roughening.

15. The method of claim 1 wherein the apparatus is a PVD apparatus.

16. The method of claim 1 wherein the apparatus is an ALD apparatus.

17. The method of claim 16 wherein the ALD apparatus comprises a reaction chamber having an interior sidewall, and wherein the component is the interior sidewall of the reaction chamber.

18. The method of claim 1 wherein the apparatus is a CVD apparatus.

19. The method of claim 18 wherein the CVD apparatus comprises a reaction chamber having an interior sidewall, and wherein the component is the interior sidewall of the reaction chamber.

20. The method of claim 18 wherein the apparatus is a MOCVD apparatus.

21. A component treated by the method of claim 1.

22. The component of claim 21 being a component of an ALD apparatus.

23. The component of claim 21 being a component of a CVD apparatus.

24. The component of claim 21 being a component of a PVD apparatus.

25. A method of treating a region of a PVD component, comprising:
forming a pattern of projections along the region;
bending the projections; and
exposing the projections to one or both of mechanical roughening and chemical etching to form microstructures on the projections.

26. The method of claim 25 wherein the component is not a sputtering target.

27. The method of claim 25 wherein the component is a coil.

28. The method of claim 27 wherein the coil is an annular ring and has a radially inner periphery and a radially outer periphery of the ring; and wherein the treated region is along the radially inner periphery of the ring.

29. The method of claim 27 wherein the coil is an annular ring and has a radially inner periphery and a radially outer periphery of the ring; and wherein the treated region is along the radially outer periphery of the ring.

30. The method of claim 27 wherein the coil is an annular ring and has a radially inner periphery and a radially outer periphery of the ring; and wherein the treated region is along the radially inner periphery of the ring and along the radially outer periphery of the ring.

31. The method of claim 25 wherein the component is a cup.

32. The method of claim 25 wherein the component is a pin.

33. The method of claim 25 wherein the component is a shield.

34. The method of claim 25 wherein the component is a cover ring.

35. The method of claim 25 wherein the component is a clamp.

36. The method of claim 25 wherein the component is an interior sidewall of a PVD reaction chamber.

37. The method of claim 25 wherein the projections are bent prior to exposing the projections to the one or both of the mechanical roughening and the chemical etching.

38. The method of claim 25 wherein the projections are bent after exposing the projections to the one or both of the mechanical roughening and the chemical etching.

39. The method of claim 25 wherein the pattern of projections is formed as a scroll pattern by utilizing a CNC tool to cut into the region of the component.

40. The method of claim 25 wherein the projections are exposed to the mechanical roughening, and wherein the mechanical roughening comprises exposure of the projections to a rigid bristles.

41. The method of claim 25 wherein the projections are exposed to the mechanical roughening, and wherein the mechanical roughening comprises exposure of the projections to a pressurized stream of particles.

42. The method of claim 41 wherein the particles comprise one or both of solid H₂O and solid CO₂.

43. The method of claim 41 wherein the particles comprise a salt.

44. The method of claim 43 wherein the salt is soluble in water.

45. The method of claim 44 wherein the salt is a salt of bicarbonate.

46. The method of claim 41 wherein the particles comprise one or both of silicon carbide and aluminum oxide; and wherein the exposure of the region to the pressurized stream comprises utilization of a pressure of less than 20 psi within the stream during the exposure.

47. The method of claim 41 wherein the particles comprise one or both of silicon carbide and aluminum oxide; and further comprising brushing the region after the exposure to the particles.

48. The method of claim 41 wherein the particles comprise one or both of silicon carbide and aluminum oxide; and further comprising exposing the region to a stream of cleaning agent after the exposure to the particles.

49. The method of claim 48 wherein the cleaning agent comprises one or both of solid H₂O and solid CO₂.

50. The method of claim 25 wherein the projections are exposed to the chemical etching, and wherein the chemical etching comprises exposure of the projections to a basic solution.

51. The method of claim 25 wherein the projections are exposed to the chemical etching, and wherein the chemical etching comprises exposure of the projections to an acidic solution.

52. The method of claim 25 wherein the projections are exposed to both the chemical etching and the mechanical roughening.

53. The method of claim 25 wherein the bent projections have bases, wherein the region of the component has a surface extending between the bases of the bent projections, and wherein the bent projections have a maximum height above the surface of from about 0.0001 inches to about 0.01 inches.

54. The method of claim 25 wherein a periodic repeat of the bent projections across the region occurs in a distance of from about 0.0001 inches to about 1 inch.

55. A PVD component treated by the method of claim 25.

56. The PVD component of claim 55 being a coil.

57. The PVD component of claim 56 wherein the coil is an annular ring and has a radially inner periphery and a radially outer periphery of the ring; and wherein the treated region is along the radially inner periphery of the ring.

58. The PVD component of claim 56 wherein the coil is an annular ring and has a radially inner periphery and a radially outer periphery of the ring; and wherein the treated region is along the radially outer periphery of the ring.

59. The PVD component of claim 56 wherein the coil is an annular ring and has a radially inner periphery and a radially outer periphery of the ring; and wherein the treated region is along the radially inner periphery of the ring and along the radially outer periphery of the ring.

60. The PVD component of claim 55 being a cup.

61. The PVD component of claim 55 being a shield.

62. The PVD component of claim 55 being a cover ring.

63. The PVD component of claim 55 being a clamp.
